(19) United States
(12) Patent Application Publication
(10) Pub. No.: US 2024/0196760 A1
(43) Pub. Date: Jun. 13, 2024

(54) CRYOGENIC SUPERCONDUCTIVE ELECTRONIC ASSEMBLY

(71) Applicant: University of Tennessee Research Foundation, Knoxville, TN (US)

(72) Inventors: Shamiul Alam, Knoxville, TN (US); Ahmedullah Aziz, Knoxville, TN (US); Mazharul Islam, Knoxville, TN (US)

(21) Appl. No.: 18/537,534

(22) Filed: Dec. 12, 2023

Related U.S. Application Data
(60) Provisional application No. 63/431,765, filed on Dec. 12, 2022.

(51) Int. Cl. H10N 60/35; G01R 33/035; G11C 11/44; H03K 19/195; H10N 69/00

(52) U.S. Cl. CPC H10N 60/35; G01R 33/0354; G11C 11/44; H03K 19/195; H10N 69/00; G06N 10/40

(57) ABSTRACT

A cryogenic superconductive electronic assembly employable as a cryogenic superconductive logic gate assembly for control processors, and employable as a cryogenic superconductive memory array for memory devices and systems, is provided. Applications of use include quantum computers and superconducting electronics, as well as spacecraft electronics, among other possibilities. In varying implementations, the cryogenic superconductive electronic assembly is furnished with one or more superconducting quantum interference devices (SQUIDs) that are incorporated with a ferroelectric (FE) material, and are furnished with one or more heater cryotron (hTron) devices.

### CROSS-REFERENCE TO RELATED APPLICATION

This application claims the benefit of U.S. Provisional Patent Application No. 63/431,765, with a filing date of Dec. 12, 2022, the contents of which are hereby incorporated by reference in their entirety.

### TECHNICAL FIELD

The present disclosure relates generally to cryogenic and superconducting computing and, more particularly, to control processor and memory device electronics employed in cryogenic and superconducting computing applications.

### BACKGROUND

Cryogenic computing, in general, involves the operation of electronic devices at cryogenic temperatures which can be 4 Kelvin (K) and below. Quantum computers and superconducting electronics, as well as spacecraft electronics, are example applications that utilize cryogenic computing. High resolution and high precision measurement and computing operations, for instance, are often most suitably executed via cryogenic computing. Certain cryogenic computing applications employ superconducting quantum interference devices (SQUIDs). SQUIDs are magnetic sensors of the highest sensitivity, and are among the basic building blocks of quantum computers and superconducting electronics. Furthermore, known quantum computing systems generally have three main components in their construction: a quantum substrate, a control processor, and a memory device. But compatibility among the components—and particularly of control processors and memory devices with qubits—in terms of operating temperature, speed, and power remains a challenge.

### SUMMARY

In an embodiment, a cryogenic superconductive logic gate assembly may include an electrode substrate, a ferroelectric (FE) layer, one or more superconducting quantum interference devices (SQUID), and a heater cryotron device. The FE layer is carried by the electrode substrate. The FE layer exhibits a first polarization state or a second polarization state based upon application of a voltage input across the FE layer. The SQUID(s) resides on the FE layer. The heater cryotron device is situated near the SQUID(s). Amid use, a superconducting state of the SQUID(s) is effected at the first polarization state of the FE layer, constituting a logic state zero (0) of the cryogenic superconductive logic gate assembly. And a nonsuperconducting state of the SQUID(s) is effected at the second polarization state of the FE layer, constituting a logic state one (1) of the cryogenic superconductive logic gate assembly.

In an embodiment, a cryogenic superconductive memory array may include an electrode substrate, a ferroelectric (FE) layer, a multitude of superconducting quantum interference devices (SQUIDs), and a multitude of heater cryotron devices. The FE layer is carried by the electrode substrate. The SQUIDs reside on the FE layer. The heater cryotron devices are situated near the SQUIDs. Heater cryotron devices and SQUIDs that are situated near each other have a series arrangement with respect to each other. Amid use, in order to execute read and write operations of the cryogenic superconductive memory array, a polarization state of the FE layer can be switched between first and second polarization states by way of application of a voltage input across the FE layer.

In an embodiment, a cryogenic superconductive electronic assembly may include a cryogenic superconductive electronic assembly and a cryogenic superconductive memory array. The cryogenic superconductive logic gate assembly may include a first electrode substrate, a first ferroelectric (FE) layer, one or more first superconducting quantum interference devices (SQUID), and a first heater cryotron device. The first FE layer is carried by the first electrode substrate. The first FE layer exhibits a first polarization state or a second polarization state based upon application of a voltage input across the first FE layer. The first SQUID(s) resides on the first FE layer. The first heater cryotron device is situated near the first SQUID(s). Amid use, a superconducting state of the first SQUID(s) is effected at the first polarization state of the first FE layer, constituting a logic state zero (0)) of the cryogenic superconductive logic gate assembly. And a nonsuperconducting state of the first SQUID(s) is effected at the second polarization state of the first FE layer, constituting a logic state one (1) of the cryogenic superconductive logic gate assembly. The cryogenic superconductive memory array may include a second electrode substrate, a second ferroelectric (FE) layer, a multitude of second superconducting quantum interference devices (SQUIDs), and a multitude of second heater cryotron devices. The second FE layer is carried by the second electrode substrate. The second SQUIDs reside on the second FE layer. The second heater cryotron devices are situated near the second SQUIDs. Second heater cryotron devices and second SQUIDs that are situated near each other have a series arrangement with respect to each other. Amid use, in order to execute read and write operations of the cryogenic superconductive memory array, a polarization state of the second FE layer can be switched between first and second polarization states by way of application of a voltage input across the second FE layer.

### BRIEF DESCRIPTION OF THE DRAWINGS

One or more aspects of the disclosure will hereinafter be described in conjunction with the appended drawings, wherein like designations denote like elements, and wherein:

FIG. 1 depicts an architecture of an embodiment of a quantum computing system with a control processor and a memory device:

FIG. 2a is a schematic of an embodiment of a cryogenic superconductive electronic assembly that can be employed as a cryogenic superconductive logic gate assembly:

FIG. 2b is a graph presenting voltage (V) of a lead zirconate titanate (PZT) ferroelectric (FE) material on an x-axis, and presenting polarization (μC/cm²) of the FE material on a y-axis:

FIG. 2c is a graph presenting voltage (mV) of a ferroelectric (FE) superconducting quantum interference device (SQUID) on an x-axis, and presenting current (μA) of the FeSQUID on a y-axis:

FIG. 2d is a table that presents polarization states, logic states, and device states of the cryogenic superconductive electronic assembly:

FIG. 3(a) is a schematic of an embodiment of a COPY logic gate that is not cascadable;

FIG. 3(b) is a schematic of an embodiment of a COPY logic gate with a heater cryotron device that is cascadable;

FIG. 3(c) is a graph of I-V characteristics of the heater cryotron device showing a gate current-controlled superconducting to resistive switching, with time (arbitrary units, a.u.) on an x-axis and with current (I) for a gate and a channel of the heater cryotron device on a y-axis:

FIG. 4(a) is a schematic of an embodiment of a COPY logic gate:

FIG. 4(b) demonstrates the COPY logic gate with a logic zero (O) input:

FIG. 4(c) demonstrates the COPY logic gate with a logic one (1) input:

FIG. 4(d) is a schematic of an embodiment of a NOT logic gate:

FIG. 4(e) demonstrates the NOT logic gate with a logic zero (0) input:

FIG. 4(f) demonstrates the NOT logic gate with a logic one (1) input:

FIG. 4(g) presents simulated results of the COPY and NOT logic gates of FIGS. 4(a)-(f), with time (ns) on an x-axis and with voltage on a y-axis:

FIG. 5a is a schematic of an embodiment of an AND logic gate with a logic zero (0) at both input terminals:

FIG. 5b demonstrates the AND logic gate with a logic zero (0) at one input terminal and logic one (1) at the other input terminal:

FIG. 5c demonstrates the AND logic gate with a logic one (1) at both input terminals:

FIG. 5d is a schematic of an embodiment of an OR logic gate with a logic zero (0) at both input terminals:

FIG. 5e demonstrates the OR logic gate with a logic zero (0) at one input terminal and logic one (1) at the other input terminal:

FIG. 5f demonstrates the OR logic gate with a logic one (1) at both input terminals:

FIG. 5g is a schematic of an embodiment of an XOR logic gate built cascading FeSQUID-based NOT, AND, and OR logic gates:

FIG. 5h presents simulated results of two-input AND, OR, and XOR logic gates of FIGS. 5a-g, with time (ns) on an x-axis and with voltage on a y-axis:

FIG. 6a is a schematic of an embodiment of a cryogenic superconductive electronic assembly that can be employed as a cryogenic superconductive memory array;

FIG. 6b is a graph presenting voltage (V) of a lead zirconate titanate (PZT) ferroelectric (FE) material on an x-axis, and presenting polarization (μC/cm²) of the FE material on a y-axis:

FIG. 6c is a graph presenting voltage (mV) of a ferroelectric (FE) superconducting quantum interference device (SQUID) on an x-axis, and presenting current (μA) of the FeSQUID on a y-axis:

FIG. 7 presents an embodiment of a modeling approach of the FeSQUID:

FIG. 8 shows a schematic of an embodiment of a heater cryotron device, and a graph of I-V characteristics of the heater cryotron device showing a gate current-controlled superconducting to resistive switching, with time (arbitrary units, a.u.) on an x-axis and with current (I) for a gate and a channel of the heater cryotron device on a y-axis:

FIG. 9a is a schematic of an embodiment of a cryogenic superconductive memory array that is FeSQUID-based and that employs a heater cryotron device as an access device:

FIG. 9b is a table that presents a biasing scheme to write into/read from a specific cell (for example, (2, 2) cell) in the array:

FIG. 10a is a graph illustrating time dynamics of the read operation with time (ns) on an x-axis and with current of a read word-line (I_{RWL}) and current of read bit-lines (I_{RBL}) on a y-axis:

FIG. 10b is a graph illustrating time dynamics of the read operation with time (ns) on an x-axis and with voltage V_{SQUID} of the accessed (2, 2) cell on a y-axis:

FIG. 11a is a graph illustrating time dynamics of write operations with time (ns) on an x-axis and with voltage (V) of ferroelectric (FE) material of cells on a y-axis:

FIG. 11b is a graph illustrating time dynamics of write ‘0’ operation with time (ns) on an x-axis and with switching of polarization of ferroelectric (FE) material (P_{FE}) and critical current of a superconducting quantum interference device (SQUID) (I_{C}) of cells on a y-axis:

FIG. 11c is a graph illustrating time dynamics of write ‘l’ operation with time (ns) on an x-axis and with switching of polarization of ferroelectric (FE) material (P_{FE}) and critical current of a superconducting quantum interference device (SQUID) (I_{C}) of cells on a y-axis; and

FIG. 12 is a table that presents a comparison of an embodiment of a cryogenic superconductive memory array (“This work”) with existing technologies (“Cryo CMOS,” “JJ-based,” “Magnetic JJ”).

### DETAILED DESCRIPTION

Referring generally to the drawings, embodiments of a cryogenic superconductive electronic assembly are depicted in the figures and described herein. The cryogenic superconductive electronic assembly is employable as a cryogenic superconductive logic gate assembly for control processors, and as a cryogenic superconductive memory array for memory devices and systems, according to varying embodiments. Applications of use include quantum computers and superconducting electronics, as well as spacecraft electronics, among other possibilities. As set forth herein, embodiments of the cryogenic superconductive electronic assembly are furnished with one or more superconducting quantum interference devices (SQUIDs) that are incorporated with a ferroelectric (FE) material, and are furnished with one or more heater cryotron (hTron) devices. Unlike past approaches, the cryogenic superconductive electronic assembly has proven to be more readily scalable, exhibits non-volatility, and has increased energy efficiency. Furthermore, the FeSQUID(s) provides switchable polarization states and voltage controllability, as described below. Enhanced compatibility between control processors and memory devices and systems is attainable with the integrated use of the cryogenic superconductive logic gate assembly and the cryogenic superconductive memory array. Compared to the past approaches, the cryogenic superconductive logic gate assembly and memory array described herein can offer a minimized mismatch in terms of speed, power consumption, operating temperature, and fabrication process. Moreover, the cryogenic superconductive logic gate assembly and memory array provide a more promising facilitation of large-scale development of quantum computing and superconducting electronics. Still, a particular embodiment of the cryogenic superconductive electronic assembly may exhibit only one, all, or a combination of, the advancements set forth herein, none of the advancements, or yet other advancements unmentioned.

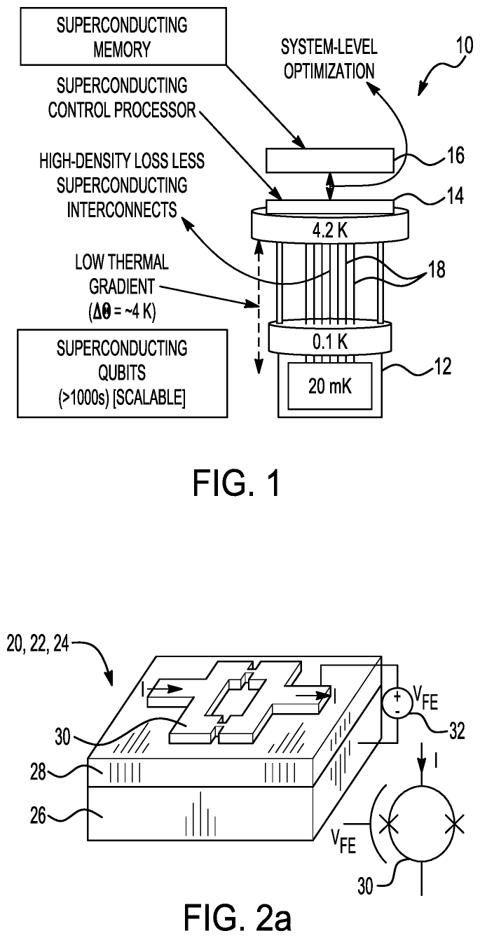

With reference now to FIG. 1, an architecture of an embodiment of a quantum computing system 10 is presented. The quantum computing system 10 includes, as its primary components, a quantum substrate 12, a control processor 14, and a memory device 16. The quantum substrate 12 is made-up of superconducting qubits, per this embodiment, which are placed at a few milli-Kelvin (mK) temperature amid operation and use. Wires and interconnects 18 extend between the quantum substrate 12 and the control processor 14. For optimized functionality and performance of the quantum computing system 10, a thermal gradient of interconnects connecting the quantum substrate 12, control processor 14, and memory device 16 should be minimized, and the components should be placed at similar temperatures relative to one another. Still, the quantum computing system 10 could have more, less, and/or different components in different embodiments.

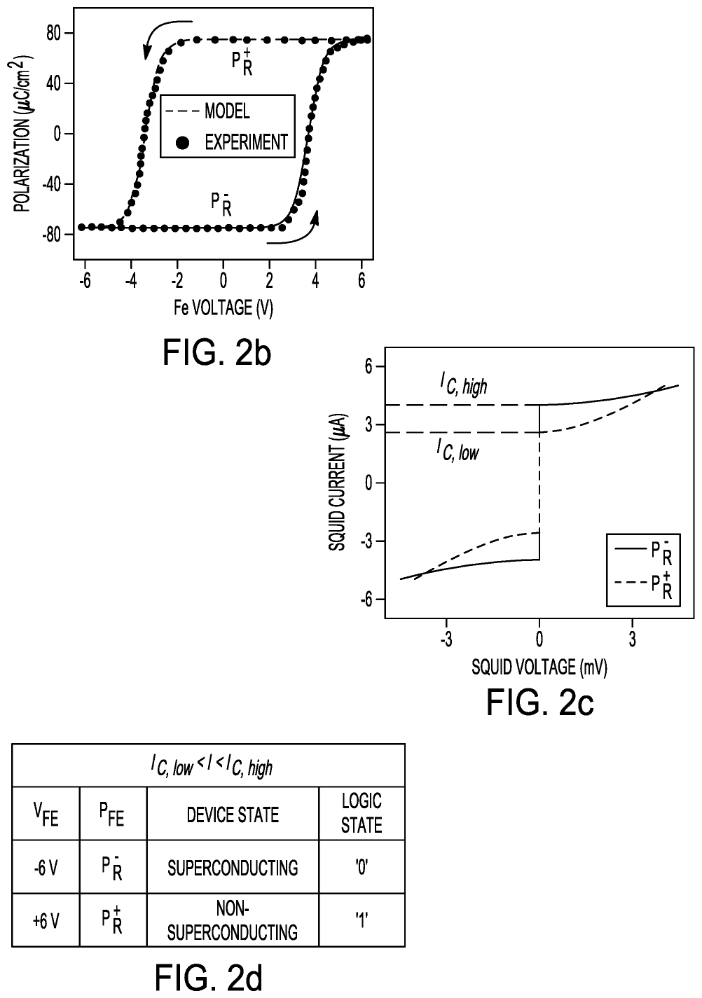

An embodiment of a cryogenic superconductive electronic assembly 20 is depicted in FIG. 2a. The cryogenic superconductive electronic assembly 20 can take the form of a cryogenic superconductive logic gate assembly 22 for use with the control processor 14, or can take the form of a cryogenic superconductive memory array 24 for use with the memory device 16. The cryogenic superconductive electronic assembly 20—as well as the cryogenic superconductive logic gate assembly and memory array 22, 24—can have different designs, constructions, and components according to varying embodiments. In the embodiment of FIG. 2a, the cryogenic superconductive electronic assembly 20 includes an electrode substrate 26, a ferroelectric (FE) layer 28, and one or more superconducting quantum interference devices (SQUIDs) 30; still, the cryogenic superconductive electronic assembly 20 could have more, less, and/or different components in different embodiments. The electrode substrate 26 carries the FE layer 28 and the SQUID(s) 30, and constitutes the lowermost layer of the cryogenic superconductive electronic assembly 20. The material composition of the electrode substrate 26 can vary according to different embodiments. In an example, the electrode substrate 26 is composed of a SrRuO₃ material, but could be composed of other materials in other examples. Furthermore, the thickness value of the electrode substrate 26 can vary according to different embodiments. In an example, the electrode substrate 26 has a thickness value of approximately fifteen (15) nanometers (nm), but could have other thickness values in other examples.

The FE layer 28 introduces the use of ferroelectric material with the SQUID(s) 30 in order to tune the superconductivity of the SQUID(s) 30. Ferroelectric materials, in general, have shown voltage-controlled, non-volatile switchability of its accompanying electric polarization state. Ferroelectric materials are dielectric materials. The FE layer 28 can retain polarization and is switchable between a first polarization state and a second polarization state via application of an external voltage input 32 and electric field across the FE layer 28 amid use of the cryogenic superconductive electronic assembly 20. It has been found that the use of the FE layer 28 with the SQUID(s) 30—i.e., a ferroelectric SQUID, or FeSQUID—imparts voltage-controlled and non-volatile switching of a critical current (I_{C}) of the SQUID(s) 30, which facilitates the use of an FeSQUID in a cryogenic circuit/system level such as in the cryogenic superconductive logic gate assembly 22, per an embodiment. In FIG. 2a, the FE layer 28 resides atop the electrode substrate 26 and is carried by the electrode substrate 26. The ferroelectric material composition of the FE layer 28 can vary in different embodiments. The material of the FE layer 28 can be based upon, among other potential factors, suitable matching of lattice structures with the material of the SQUID(s) 30. In an example, the FE layer 28 is composed of a PbZr_{0.2}Ti_{0.8}O₃ (PZT) material, but could be composed of other materials in other examples. Furthermore, the thickness of the FE layer 28 can vary according to different embodiments. In an example, the FE layer 28 has a thickness value of approximately seventy (70) nanometers (nm), but could have other thickness values in other examples.

The SQUID(s) 30 is fabricated on, and resides atop, the FE layer 28, as illustrated in FIG. 2a. A single SQUID is also presented in circuit diagrammatic form in the figure. The SQUID(s) 30 constitutes the uppermost layer of the cryogenic superconductive electronic assembly 20, according to this embodiment.

Superconducting quantum interference devices, in general, are among the basic building blocks of superconducting circuits and systems. The SQUID(s) 30 in FIG. 2a has a pair of weakened links in a parallel arrangement relative to each other. The SQUID(s) 30 has a planar configuration. Similar to the previous components of the cryogenic superconductive electronic assembly 20, the material composition of the SQUID(s) 30 can vary according to different embodiments. In an example, the SQUID(s) 30 is composed of a αMo₈₀Si₂₀ material, but could be composed of other materials in other examples. Furthermore, the thickness of the SQUID(s) 30 can vary according to different embodiments. In an example, the SQUID(s) 30 has a thickness value of approximately fifteen (15) nanometers (nm), but could have other thickness values in other examples.

With reference to the graph of FIG. 2b, the voltage-controlled non-volatile switching of internal polarization (P_{FE}) of the ferroelectric material PZT is demonstrated. In the ferroelectric material, the internal polarization P_{FE} effects a surface charge that induces an electric field and injects direct charge. In the graph, the first polarization state is indicated by P_{R}⁻, and the second polarization state is indicated by P_{R}⁺. When the SQUID(s) 30 is fabricated on top of the FE layer 28, it has been found that the superconducting layer screens the charge bound in the interface. This bound charge in the surface of the interface ( [symbol] P_{R}.dA, where P_{R} is the remnant P_{FE} and A is the surface area) directly depends on the remnant P_{FE}—negative P_{R} (P_{R}⁻) increases the bound charge in the surface of the interface, whereas positive P_{R} (P_{R}⁺) results in an opposite effect. The resulting change in the carrier density impacts a critical temperature (T_{C}) and hence the superconducting energy gap (Δ). The dependence of Δ on T_{C} is given by the Bardeen-Cooper-Schrieffer (BCS) theory (equation 1):

$$Δ ( T ) = 1.763 {k}_{B} {T}_{C} tanh ( 2.2 \sqrt{\frac{{T}_{C}}{T} - 1} )$$

where T is the temperature and kB is the Boltzmann constant. According to the Ambegaokar-Baratoff (AB) theory, Δ(T) determines the critical current (I_{C}) as provided by (equation 2):

$${I}_{c} = \frac{π Δ}{2 {q}_{e} {R}_{N}} tanh ( \frac{Δ}{2 {k}_{B} T} )$$

where qₑ is the charge of an electron and R_{N} is the normal state resistance of the SQUID(s) 30.

Accordingly, based on the two non-volatile first and second polarization states P_{R}⁻, P_{R}⁺ of the FE layer 28, which are controlled by the voltage input 32, two levels of critical current I_{C} are observable in the I-V characteristics of the FE layer's first and second polarization states P_{R}⁻, P_{R}⁺, as demonstrated in the graph of FIG. 2c—particularly, a first or high critical current (I_{C,high}) level for the SQUID(s) 30 arises, and a second or low critical current (I_{C,low}) level for the SQUID(s) 30 arises. In this embodiment, the voltage-controllability of superconductivity of the FE layer 28 and SQUID(s) 30 is utilized to design and construct basic Boolean logic gates and logic family for cryogenic applications such as in the cryogenic superconductive logic gate assembly 22 for use with the control processor 14. FIG. 2d is a table that presents polarization states, logic states, and device states of the cryogenic superconductive electronic assembly 20 and of the cryogenic superconductive logic gate assembly 22, according to this embodiment. The table demonstrates, in part, how the FE layer 28 and SQUID(s) 30 were utilized to design and construct basic Boolean logic gates and logic family. With reference to the table, the first polarization state P_{R}⁻ of the FE layer 28 establishes a logic state zero (0) of a cryogenic superconductive logic gate such as the cryogenic superconductive logic gate assembly 22, and the second polarization state P_{R}⁺ of the FE layer 28 establishes a logic state one (1) of the cryogenic superconductive logic gate. The logic states zero (0) and one (1) can be switched by applying the voltage input 32 (V_{FE} in the table).

Further, in this embodiment, and as can be observed from FIG. 2b, while the coercive voltage input 32 of the ferroelectric material PZT is approximately 3 volts (V), a greater voltage input 32 value is used—negative −6 V for logic state zero (0) and positive +6 V for logic state one (1)—in order to more readily ensure that the FE layer 28 remains in the first polarization state P_{R}⁻ or in the second polarization state P_{R}⁺, as intended. Still, in other embodiments, the magnitude of the voltage input 32 can be decreased with the use of differing ferroelectric materials for the FE layer 28 and with differing dimensions of the FE layer 28. In the embodiment of the figures, the logic state zero (0) corresponds to the high critical current (I_{C,high}), and the logic state one (1) conversely corresponds to the low critical current (I_{C,low}). When the FE layer 28 and SQUID(s) 30 (collectively, FeSQUID) are biased with a bias current (I_{C,low}<I<I_{C,high}), the FeSQUID with logic state zero (0) corresponds to a superconducting state of the SQUID(s) 30, and the FeSQUID with logic state one (1) corresponds to a nonsuperconducting state of the SQUID(s) 30. Based on the superconducting or nonsuperconducting state of the SQUID(s) 30, the bias current will flow either through the SQUID(s) 30 (i.e., superconducting state) or through a circuitry external of the SQUID(s) 30 (i.e., nonsuperconducting state). This phenomenon and functionality are harnessed in order to design and construct FeSQUID-based Boolean logic gates for cryogenic applications.

The effective operation of the FeSQUID-based Boolean logic gates was demonstrated via simulation. A circuit compatible compact model for the FeSQUID was developed in the modeling language Verilog-A and was calibrated with experimental observation. The non-volatile switching of the polarization of the FE layer 28 was modeled using the following Preisach model equation (equation 3):

$${P}_{FE} = {P}_{S} tanh [ \frac{1}{2 {E}_{C}} ln ( \frac{{P}_{S} + {P}_{R}}{{P}_{S} - {P}_{R}} ) ( {E}_{FE} ∓ {E}_{C} ) + {P}_{off} ]$$

where P_{S} is the saturation polarization of the ferroelectric material of the FE layer 28, P_{R} is the remnant polarization of the ferroelectric material of the FE layer 28, and P_{off} is the offset polarization of the ferroelectric material of the FE layer 28, E_{C} is the coercive field across the FE layer 28, and E_{FE} is the applied electric field across the FE layer 28. FIG. 2b evidences validation of the P_{FE}-V characteristics of the ferroelectric material PZT with experimental results. The dependence of the critical temperature T_{C} on the internal polarization P_{FE} of the ferroelectric material was phenomenologically implemented using a look-up-table-based approach. Equation 1 above was used to calculate Δ(T), and equation 2 above was subsequently used to calculate the critical current I_{C} of the SQUID(s) 30. The I-V characteristics of the SQUID(s) 30 was modeled by utilizing the following equation (equation 4):

$$V = \{ \begin{matrix}0 , & I < {I}_{C} \\ I \times {R}_{N} , & I \geq {I}_{C}\end{matrix}$$

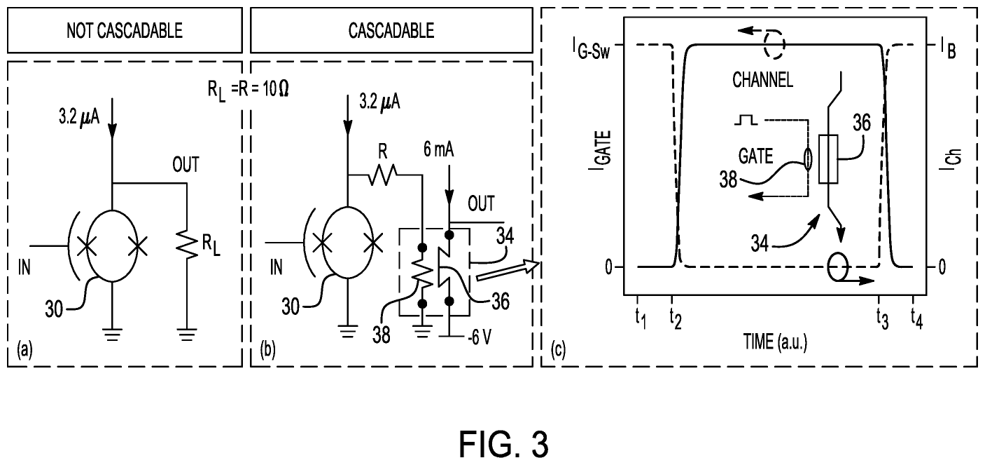

Oftentimes, for application and use of logic gates, an important functionality is the capability of implementing fan-out. For a cascadable logic circuit system, outputs of logic gates should be sufficient to drive inputs of logic gates of a subsequent stage. It has been found that, for an FeSQUID, in order to drive a logic gate input by a logic gate output, voltage at the logic gate output should have a magnitude great enough to set the intended polarization state of the ferroelectric material and FE layer 28 of the FeSQUID. FIG. 3(a) presents an embodiment of a FeSQUID-based COPY logic gate in circuit diagrammatic form. With reference back to FIG. 2c, it can be observed that the low critical current (I_{C,low}) of the FeSQUID has a value of approximately 2.6 μA, and the high critical current (I_{C,high}) of the FeSQUID has a value of approximately 4 μA, per this example. Further, the resistance value for Rx for the first polarization state P_{R}⁻ was 0.95 k≤2, and the resistance value for Rx for the second polarization state P_{R}⁺ was 1.75 kΩ. It has been determined that for proper operation of the COPY logic gate of FIG. 3(a), the value of an external resistance (R) should be selected such that when the FeSQUID becomes resistive, substantially all of the accompanying bias current flows through R. Moreover, it has been determined that the bias current should satisfy the relationship I_{C,low}<I<I_{C,high}. In this example embodiment, 3.2 μA was used for I, and 10 Ω was used for R. For these current and resistance values, approximately 31 μV resulted for logic state one (1) at an output of the COPY logic gate, and approximately 0 V resulted for logic state zero (0)) at the output of the COPY logic gate. Neither of these voltage values at the output of the COPY logic gate were found to be sufficient to drive inputs of logic gates of the next stage of the FeSQUID, per this example embodiment.

To resolve the shortfall, a heater cryotron (hTron) device 34 has been introduced in the cryogenic superconductive electronic assembly 20 and in the cryogenic superconductive logic gate assembly 22, according to an embodiment, and as shown in FIGS. 3(b) and 3(c). The heater cryotron device 34 is situated near and at the output of the COPY logic gate of the figure, and could be situated near and at the output of downstream COPY logic gates or other types of logic gates in order to establish a cascadable logic circuit system. In the embodiment of FIG. 3(b), the heater cryotron device 34 is situated adjacent to the SQUID 30. FIG. 3(c) is a graph showing the I-V characteristics of the heater cryotron device 34. The heater cryotron device 34 in this embodiment is a three terminal gate current-controlled superconducting switch. The heater cryotron device 34 consists of a superconducting channel 36 and a resistive gate 38. Still, the heater cryotron device 34 could have other designs, constructions, and components in other embodiments. The superconducting channel 36 initially remains superconducting, but it has been shown that a high enough gate current (i.e., greater than the switching current) can bring the superconducting channel 36 to a resistive state. The superconducting channel 36 can be made of a superconducting nanowire, and the resistive gate 38 can be made of a normal metal. In the example simulation, a phenomenological compact model was employed for the heater cryotron device 34. With the implementation of the heater cryotron device 34, it was found that the voltage value at the output of the COPY logic gate was approximately −6 V for logic state zero (0), and +6 V for logic state one (1). Both of these voltage values at the output of the COPY logic gate were found to be sufficient to drive inputs of logic gates of the next stage of the FeSQUID, per this example embodiment.

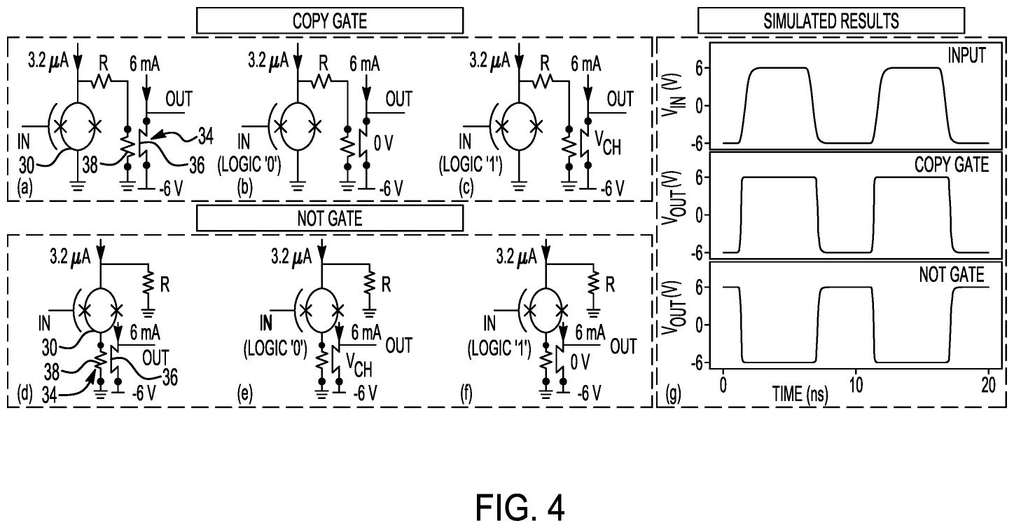

The design methodology, working principle, and simulated results for an FeSQUID-based logic family are now set forth according to an embodiment. An embodiment of a single (1) input COPY logic gate with a single FeSQUID where the input is applied as voltage across the FE layer 28 and ferroelectric material is presented in FIGS. 4(a)-(c), and an embodiment of a single (1) input NOT logic gate with a single FeSQUID where the input is applied as voltage across the FE layer 28 and ferroelectric material is presented in FIGS. 4(d)-(f). With particular reference to FIG. 4(b), for logic state zero (0)) and −6 V applied to the input (“IN”) of the COPY logic gate, and with a suitable bias current (I) applied, the SQUID exhibits I_{C,high} (>I) and becomes superconductive. Accordingly, substantially all of the accompanying bias current flows through the FeSQUID, and the resistive gate 38 of the heater cryotron device 34 does not receive sufficient current to switch the superconducting channel 36 to its resistive state. Due to appropriate biasing of the heater cryotron device 34, logic state zero (0)) and −6 V is resulted at the output (“OUT”). With particular reference now to FIG. 4(c), for logic state one (1) and +6 V applied to the input of the COPY logic gate, the SQUID becomes resistive and substantially all of the accompanying bias current flows through the resistive gate 38 of the heater cryotron device 34. The superconducting channel 36 of the heater cryotron device 34 is switched to its resistive state, and hence logic state one (1) and +6 V is resulted at the output.

In the NOT logic gate of FIGS. 4(d)-(f), the resistive gate 38 of the heater cryotron device 34 exhibits a series arrangement with respect to the FeSQUID and SQUID 30. For logic state zero (0) and −6 V applied to the input of the NOT logic gate, the FeSQUID becomes superconductive and sufficient current flows through the resistive gate 38 of the heater cryotron device 34 which, as a consequence, switches the superconducting channel 36 to its resistive state, and hence logic state one (1) and +6 V is resulted at the output, as depicted in FIG. 4(e). For logic state one (1) and +6 V applied to the input of the NOT logic gate, and with reference now to FIG. 4(f), the converse sequence of events takes place for the FeSQUID and heater cryotron device 34 (i.e., FeSQUID becomes resistive and superconducting channel 36 becomes superconducting), and hence logic state zero (0)) and −6 V is resulted at the output. Lastly, FIG. 4(g) presents simulated results of the single (1) input COPY and NOT logic gates of FIGS. 4(a)-(f), with time (ns) on an x-axis and with voltage on a y-axis. In the graph, VIN represents voltage applied to the respective input, and V_{OUT} represents voltage resulted at the respective output.

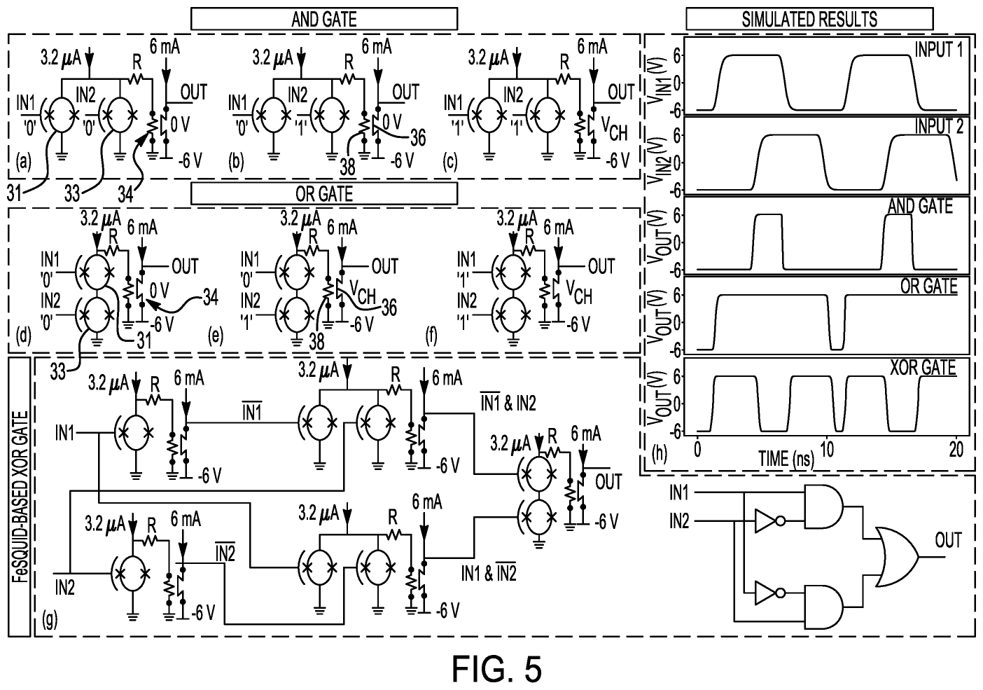

Furthermore, an embodiment of a two (2) input (IN1 and IN2 in FIGS. 5(a)-(f)) AND logic gate with a pair of FeSQUIDs where the input is applied as voltage across the FE layers 28 and ferroelectric materials of the FeSQUIDs is presented in FIGS. 5(a)-(c), and an embodiment of a two (2) input OR logic gate with a pair of FeSQUIDs where the input is applied as voltage across the FE layers 28 and ferroelectric materials of the FeSQUIDs is presented in FIGS. 5(d)-(f). In the AND logic gate of FIGS. 5(a)-(c), the two FeSQUIDs are connected in parallel; that is, a first SQUID 31 and a second SQUID 33 exhibit a parallel arrangement with respect to each other. With the parallel arrangement, if either of the two FeSQUIDs become superconductive such as in FIGS. 5(a) and 5(b)—and in the logic states zero-zero (00), zero-one (01), and one-zero (10) applied at the input (“IN1.” “IN2”)—substantially all of the accompanying bias current flows through the FeSQUID(s), and the resistive gate 38 of the heater cryotron device 34 does not receive sufficient current to switch the superconducting channel 36 to its resistive state. In FIG. 5(a), the first SQUID 31 exhibits a superconducting state, the second SQUID 33 exhibits a superconducting state, and the superconducting channel 36 exhibits a superconducting state. In FIG. 5(b), the first SQUID 31 exhibits a superconducting state, the second SQUID 33 exhibits a resistive state, and the superconducting channel 36 exhibits a superconducting state. As a consequence, logic state zero (0)) and −6 V is resulted at the output, as depicted in FIGS. 5(a) and 5(b). And as depicted in FIG. 5(c), for the logic state one-one (11) applied at the input, both of the two FeSQUIDs become resistive and substantially all of the accompanying bias current flows through the resistive gate 38 of the heater cryotron device 34 (i.e., the superconducting channel 36 is in its resistive state). As a consequence, logic state one (1) and +6 V is resulted at the output.

In the OR logic gate of FIGS. 5(d)-(f), the two FeSQUIDs are connected in series; that is, a first SQUID 31 and a second SQUID 33 exhibit a series arrangement with respect to each other. With the series arrangement, only when both of the two FeSQUIDs remain superconducting—which occurs in the logic state zero-zero (00) of FIG. 5(d)—the resistive gate 38 of the heater cryotron device 34 does not receive sufficient current to switch the superconducting channel 36 to its resistive state (i.e., the superconducting channel 36 is in its superconducting state). As a consequence, logic state zero (0)) and −6 V is resulted at the output. Conversely, for logic states zero-one (01), one-zero (10), and one-one (11) of FIGS. 5(e) and 5(f), one or both of the FeSQUIDs becomes resistive and substantially all of the accompanying bias current flows through the resistive gate 38 of the heater cryotron device 34. In FIG. 5(e), for example, the first SQUID 31 exhibits a superconducting state, the second SQUID 33 exhibits a resistive state, and the superconducting channel 36 exhibits a resistive state. In FIG. 5(f), both of the first and second SQUIDs 31, 33 exhibit a resistive state, as well as the superconducting channel 36. As a consequence, logic state one (1) and +6 V is resulted at the output. Further, an embodiment of a two (2) input XOR logic gate with the Fe-SQUID-based NOT, AND, and OR logic gates, as previously set forth, is presented in FIG. 5(g). This embodiment demonstrates the capability of the FeSQUID-based logic family to effectively handle fan-out. Lastly, FIG. 5(h) presents simulated results of the two (2) input AND, OR, and XOR logic gates of FIGS. 5(a)-(g), with time (ns) on an x-axis and with voltage on a y-axis. In the graph, VIN represents voltage applied to the respective input, and V_{OUT} represents voltage provided at the respective output.

Accordingly, these embodiments of the single (1) input COPY and NOT logic gates and the two (2) input AND, OR, and XOR logic gates have been shown to furnish CMOS-like voltage-controlled logic gates and logic family, readying them for employment in applications that include quantum computers and superconducting electronics, as well as spacecraft electronics, among other possibilities.

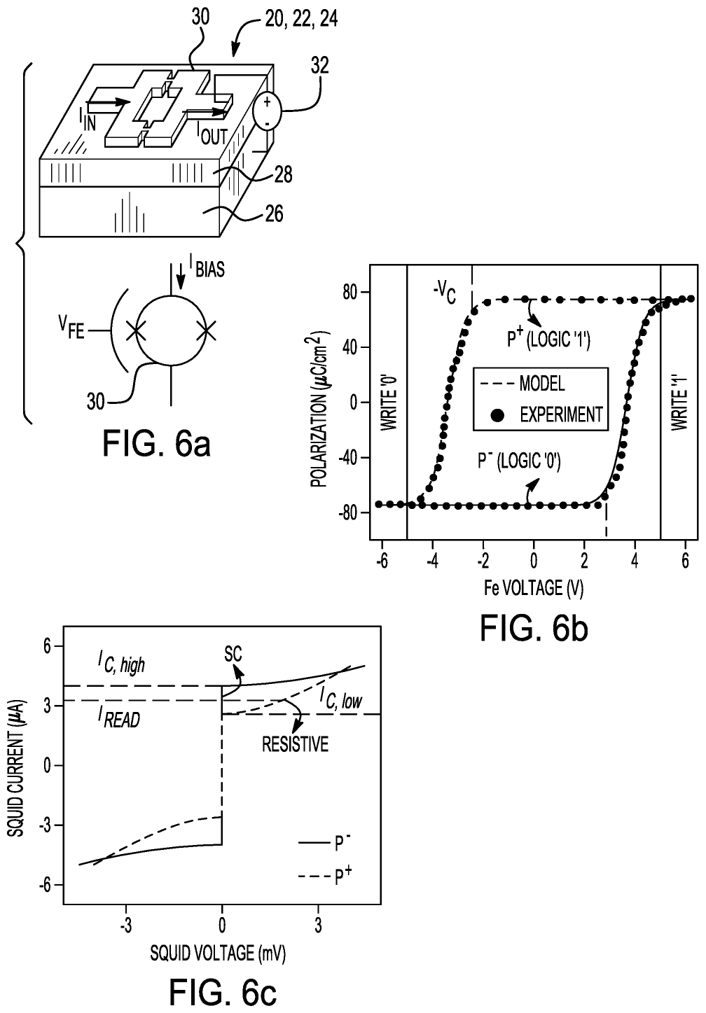

With reference now to FIGS. 6a-c, an embodiment of the cryogenic superconductive memory array 24 for use with the memory device 16 is now set forth. Many of the previous descriptions of the cryogenic superconductive electronic assembly 20 apply equally here for the cryogenic superconductive memory array 24, and may not necessarily be repeated. Known quantum algorithms often call for numerous arbitrary rotations which demand a large memory in order to store program instructions. As set forth, superconducting qubits of quantum substrates, such as the quantum substrate 12, have revealed a high sensitivity to noise and therefore, for protection against thermal disturbances, the superconducting qubits are placed at a few milli-Kelvin (mK) temperature amid operation and use. Moreover, in order to preserve the integrity of the quantum states, the superconducting qubits often undergo continuous error correction schemes, again demanding extensive memory and bandwidth. Past cryo-memory devices based on superconducting, nonsuperconducting, and hybrid technologies have been found to be disadvantaged with one or more of the following setbacks: i) limited scalability, ii) process complexity, iii) bulky peripherals, iv) array-level interference, v) volatility, and/or vi) speed incompatibility. Certain embodiments of the cryogenic superconductive memory array 24 have been designed and constructed to resolve one or more or all of these setbacks of the past cryo-memory devices.

In the embodiment of FIG. 6a, the cryogenic superconductive memory array 24 includes the electrode substrate 26, the FE layer 28, and the SQUID(s) 30; still, the cryogenic superconductive memory array 24 could have more, less, and/or different components in different embodiments. Ferroelectric materials of the cryogenic superconductive memory array 24 include PZT, as well as doped hafnium oxide (HZO) material, among other possibilities. As previously described, the polarization state of the FE layer 28 is switchable between the first and second polarization states via voltage-gating, as observable in FIG. 6b. The polarization state of the FE layer 28, whether first or second, has been shown to affect the critical current (I_{C}) of the SQUID(s) 30—FIG. 6c demonstrates this for the cryogenic superconductive memory array 24. The remnant polarization states, i.e., first polarization state (P_{R}⁻) and second polarization state (P_{R}⁺), result in two distinct levels of critical current, I_{C,high} and I_{C,low}, respectively. It has been shown possible to bias the SQUID(s) 30 with an appropriate level of current (I_{READ}) in order to selectively impart the superconducting state and behavior of the SQUID(s) 30 or the nonsuperconducting and resistive state and behavior of the SQUID(s) 30.

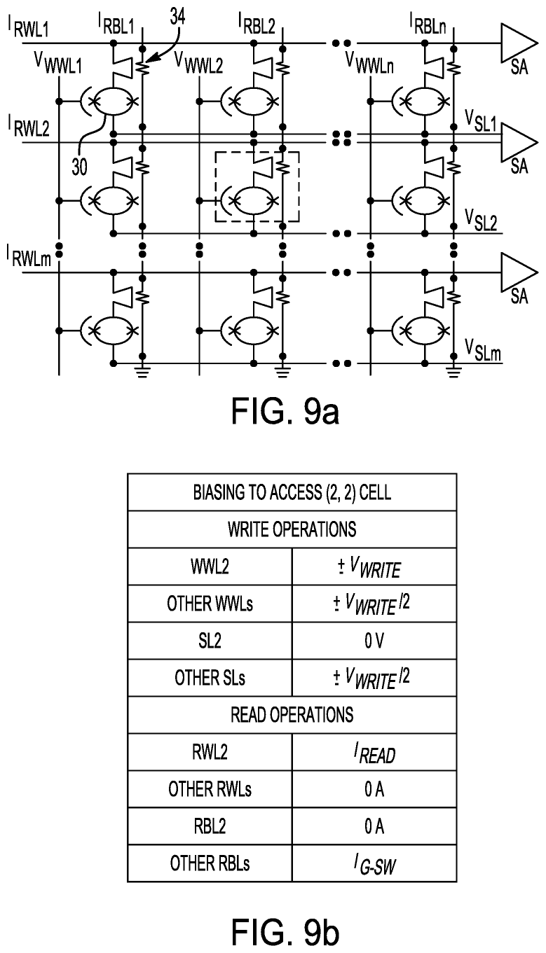

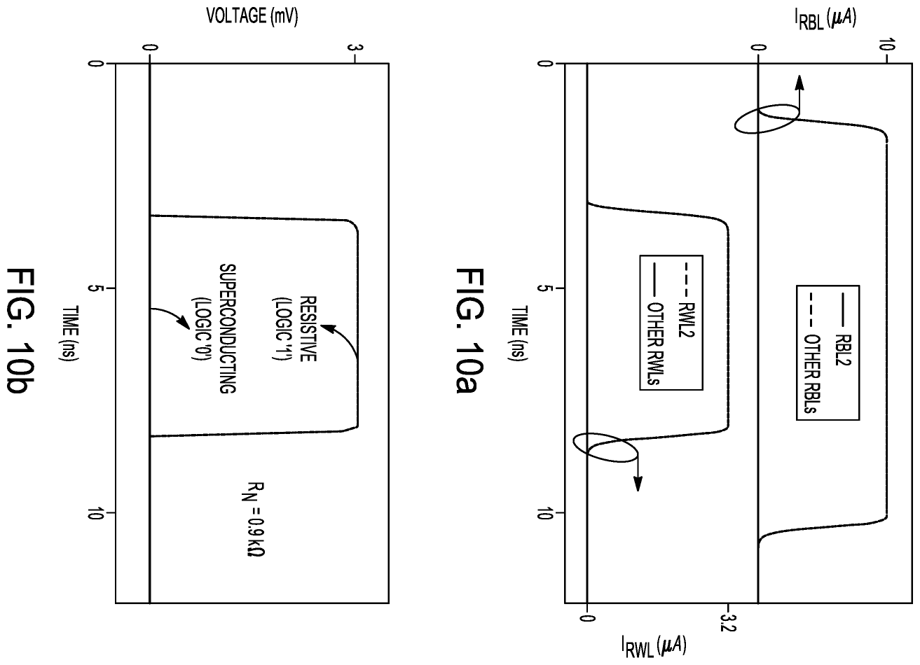

With specific reference to FIG. 6c, for |I_{C,low}|<|I_{READ}|<|I_{C,high}|, the superconducting/nonsuperconducting states of the SQUID(s) 30 for the second polarization state (P_{R}⁺)/first polarization state (P_{R}⁻) are furnished, respectively, resulting in zero/non-zero terminal voltage (V_{SQUID}). Accordingly, for the cryogenic superconductive memory array 24, it has been found that binary data can be stored in the form of ferroelectric polarization, and read by sensing V_{SQUID}. Separate and discrete read/write paths are hence effected. In this embodiment, the voltage input 32 is applied across the FE layer 28 during write operations, and current flows through the SQUID(s) 30 during read operations. These unique properties of the cryogenic superconductive memory array 24, per this embodiment, have been shown to call for the use of an unconventional access controller. With reference to FIGS. 9a and 9b, for write operations, for instance, a V/2 biasing scheme is utilized; and for read operations, the heater cryotron device 34 is set in a series arrangement with the accompanying memory cells in order to selectively provide I_{READ} to the accessed cells. With reference to FIG. 8, the heater cryotron device 34 of the cryogenic superconductive memory array 24 has the superconducting channel 36 and the resistive, metallic gate 38; still, the heater cryotron device 34 could have other designs, constructions, and components in other embodiments. The superconducting channel 36 can be made resistive by applying a gate current of sufficiently increased magnitude (I_{G}>I_{G-Sw}).

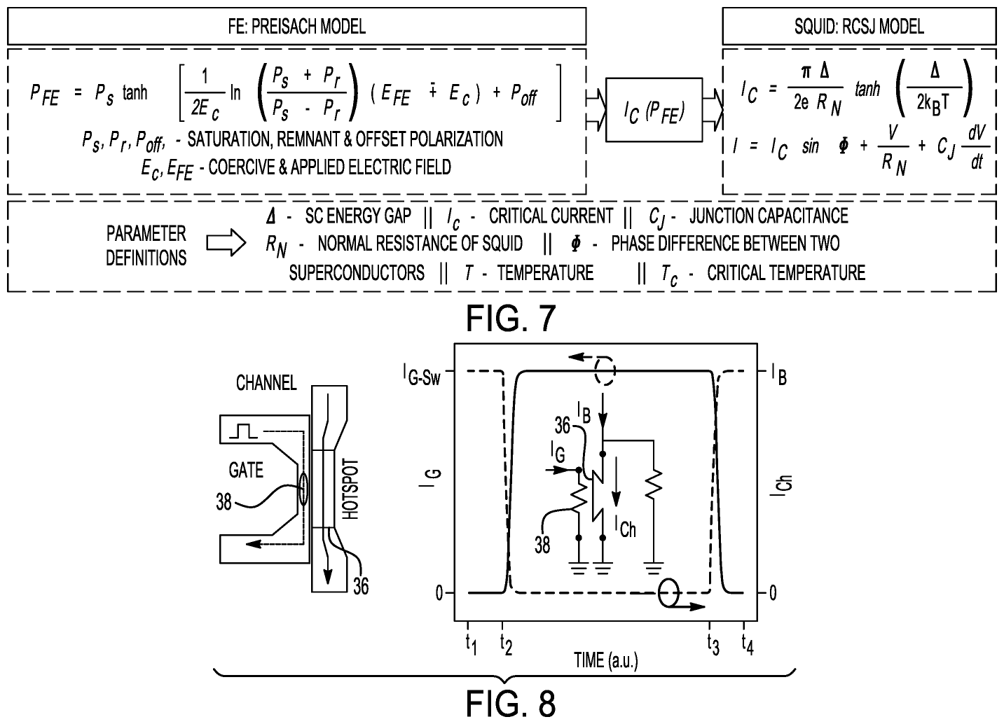

For analysis according to this embodiment, a semi-physical compact model for the FeSQUID was developed in the modeling language Verilog-A, as presented in FIG. 7. In the model, what-is-known-as the resistively and capacitively shunted junction (RCSJ) model was employed for the SQUID(s) 30, and the Preisach model was employed for the ferroelectric material of the FE layer 28. These two independent blocks were self-consistently coupled in the model to capture the effect of polarization of the FE layer 28 on the critical current (I_{C}) of the SQUID(s) 30. The model was calibrated with the embodiment of the FeSQUID having the SQUID(s) 30 with a planar configuration and composed of a αMo₈₀Si₂₀ material, and the SQUID(s) 30 being carried by the FE layer 28 composed of a PbZr_{0.2}Ti_{0.8}O₃ (PZT) material.

With reference to FIGS. 9a and 9b, an embodiment of the cryogenic superconductive memory array 24 is presented in circuit diagrammatic form, and an example of a biasing scheme to write into/read from a (2, 2) cell is presented in table form. The cryogenic superconductive memory array 24 is shown with the FeSQUID and heater cryotron device 34 exhibiting a series arrangement with respect to each other. During write operations, per this example embodiment, write word-lines (WWL) and source lines (SL) are biased with voltage in a way so that an accessed (ACC) cell (demarcated by broken line rectangle in the FIG. 9a; (2, 2) cell) receives the write voltage (±V_{WRITE}), half-accessed (HA) cells receive±½V_{WRITE}, and unaccessed (UA) cells receive 0 V across them (½|V_{WRITE}|<|coercive voltage, V_{C}|<|V_{WRITE}|). During read operations, per this example embodiment, all of the write-word lines (WWL) and source lines (SL) are kept grounded. Then, read bit-lines (RBL) are biased with current in a way so that all of the heater cryotron devices 34 situated in the same column with the accessed (ACC) cell remain superconducting, while the other heater cryotron devices 34 are made resistive. Next, per this example embodiment, when read current I_{READ} is applied to read word-lines (RWL), the heater cryotron device 34 of the accessed (ACC) cell channels the current through the accessed (ACC) cell and the accompanying SQUID(s) 30 generates either V_{SQUID}=0) for the first polarization state (P_{R}⁻) or V_{SQUID}=IREAD×RN for the second polarization state (P_{R}⁺) (where R_{N} represents the normal resistance of the SQUID(s) 30). Furthermore, it has been shown that these voltage levels can be sensed using cryogenic sense amplifiers (SA) to identify the stored binary data.

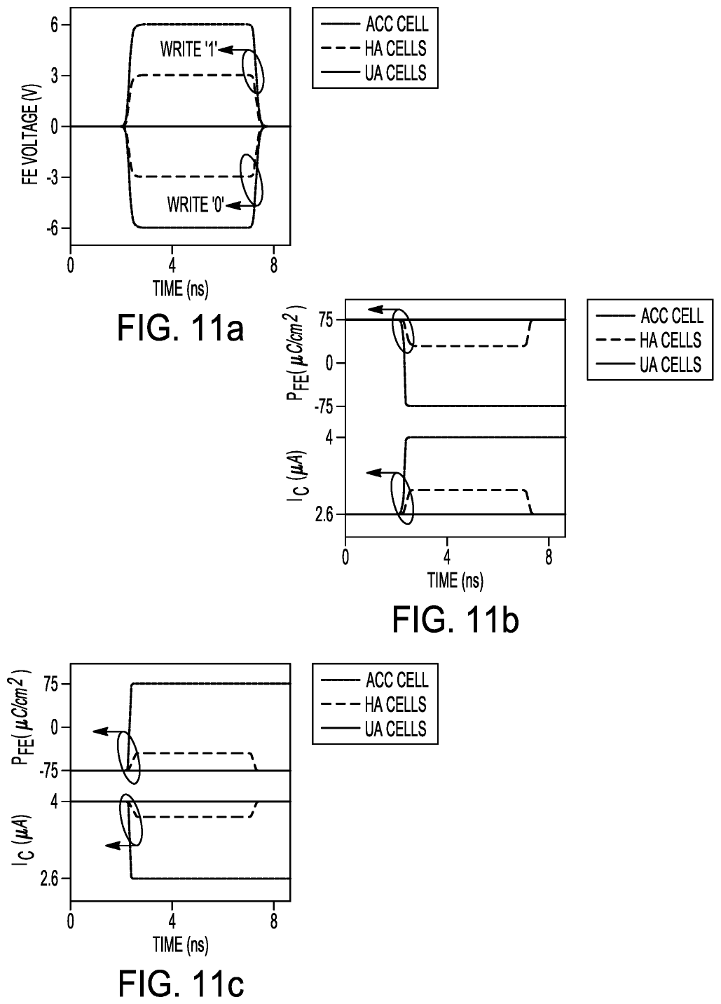

In order to test this example embodiment, a 3×3 array was simulated using the device level circuit simulator HSPICE with the Verilog-A model of FeSQUID developed using Preisach model and equations 1-3. With reference now to FIGS. 10a and 10b, during read operations per this example embodiment—and with suitable bias currents as shown in FIG. 10a—the SQUID(s) 30 remains in its superconducting state for logic state zero (0) (FIG. 10b), and the SQUID(s) 30 remains in its nonsuperconducting and resistive state for logic state one (1) (FIG. 10b). Furthermore, with reference now to FIGS. 11a-c, during write operations per this example embodiment—and upon applying suitable biases as shown in FIG. 11a—the polarization state of the accessed (ACC) cell is switchable between the second and first polarization states (P_{R}⁺↔P_{R}⁻ in FIGS. 11b and 11c). This has been found to effectively change the critical current (I_{C}) of the SQUID(s) 30 (I_{C,low}↔I_{C,high} in FIGS. 11b and 11c), and establishes a window for sensing. Accordingly, any cell can be accessed/programmed without disturbing other cells.

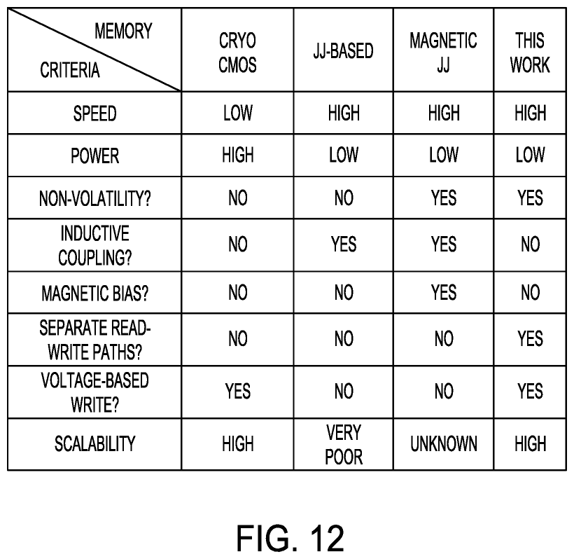

Lastly, according to this embodiment, the cryogenic superconductive memory array 24 has proven to exhibit scalability and to avert the use of inductive coupling and bulky peripheral circuits, unlike the past cryo-memory devices. Still, in other embodiments, the programing voltage of the cryogenic superconductive memory array 24 could be decreased by employing differing ferroelectric materials such as doped hafnium oxide (HZO) material, or by using a thinner FE layer 28. And, FIG. 12 is a table that presents a comparison of the cryogenic superconductive memory array 24 per this embodiment (“THIS WORK”) with certain existing technologies (“CRYO CMOS,” “JJ-BASED,” “MAGNETIC JJ”). The comparisons involved speed, power, non-volatility, inductive coupling, magnetic bias, separate read-write paths, voltage-based write, and scalability, among the technologies.

As used herein, the terms “general” and “generally” and “substantially” are intended to account for the inherent degree of variance and imprecision that is often attributed to, and often accompanies, any design and manufacturing process, including engineering tolerances—and without deviation from the relevant functionality and intended outcome—such that mathematical precision and exactitude is not implied and, in some instances, is not possible. In other instances, the terms “general” and “generally” are intended to represent the inherent degree of uncertainty that is often attributed to any quantitative comparison, value, and measurement calculation, or other representation.

It is to be understood that the foregoing is a description of one or more aspects of the disclosure. The disclosure is not limited to the particular embodiment(s) disclosed herein, but rather is defined solely by the claims below. Furthermore, the statements contained in the foregoing description relate to particular embodiments and are not to be construed as limitations on the scope of the disclosure or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

What is claimed is:

1. A cryogenic superconductive logic gate assembly, comprising:
an electrode substrate;
a ferroelectric (FE) layer carried by the electrode substrate, the FE layer exhibiting a first polarization state or a second polarization state based upon application of a voltage input across the FE layer;
at least one superconducting quantum interference device (SQUID) residing on the FE layer; and
a heater cryotron device situated adjacent the at least one superconducting quantum interference device;
wherein a superconducting state of the at least one superconducting quantum interference device is effected at the first polarization state of the FE layer, constituting a logic state zero (0) of the cryogenic superconductive logic gate assembly, and a nonsuperconducting state of the at least one superconducting quantum interference device is effected at the second polarization state of the FE layer, constituting a logic state one (1) of the cryogenic superconductive logic gate assembly.

2. The cryogenic superconductive logic gate assembly as set forth in claim 1, wherein the heater cryotron device comprises a superconducting channel and a resistive gate.

3. The cryogenic superconductive logic gate assembly as set forth in claim 1, wherein the at least one superconducting quantum interference device and the heater cryotron device exhibit a parallel arrangement with respect to each other.

4. The cryogenic superconductive logic gate assembly as set forth in claim 3, wherein the cryogenic superconductive logic gate assembly has a single input and is a cryogenic superconductive COPY logic gate assembly.

5. The cryogenic superconductive logic gate assembly as set forth in claim 1, wherein the at least one superconducting quantum interference device and the heater cryotron device exhibit a series arrangement with respect to each other.

6. The cryogenic superconductive logic gate assembly as set forth in claim 5, wherein the cryogenic superconductive logic gate assembly has a single input and is a cryogenic superconductive NOT logic gate assembly.

7. The cryogenic superconductive logic gate assembly as set forth in claim 1, wherein the at least one superconducting quantum interference device includes a first superconducting quantum interference device and a second superconducting quantum interference device, the first and second superconducting quantum interference devices exhibiting a parallel arrangement with respect to each other.

8. The cryogenic superconductive logic gate assembly as set forth in claim 7, wherein the cryogenic superconductive logic gate assembly has two inputs and is a cryogenic superconductive AND logic gate assembly.

9. The cryogenic superconductive logic gate assembly as set forth in claim 1, wherein the at least one superconducting quantum interference device includes a first superconducting quantum interference device and a second superconducting quantum interference device, the first and second superconducting quantum interference devices exhibiting a series arrangement with respect to each other.

10. The cryogenic superconductive logic gate assembly as set forth in claim 9, wherein the cryogenic superconductive logic gate assembly has two inputs and is a cryogenic superconductive OR logic gate assembly.

11. The cryogenic superconductive logic gate assembly as set forth in claim 1, wherein the cryogenic superconductive logic gate assembly has two inputs and is a cryogenic superconductive XOR logic gate assembly.

12. The cryogenic superconductive logic gate assembly as set forth in claim 1, wherein the cryogenic superconductive logic gate assembly comprises a cascading configuration of cryogenic superconductive logic gate assemblies.

13. A cryogenic superconductive memory array, comprising:
an electrode substrate;
a ferroelectric (FE) layer carried by the electrode substrate;
a plurality of superconducting quantum interference devices (SQUIDs) residing on the FE layer; and
a plurality of heater cryotron devices situated adjacent the superconducting quantum interference devices, adjacent heater cryotron devices and superconducting quantum interference devices exhibit a series arrangement with respect to each other;
wherein, in order to execute read and write operations of the cryogenic superconductive memory array, a polarization state of the FE layer is switchable between first and second polarization states via application of a voltage input across the FE layer.

14. The cryogenic superconductive memory array as set forth in claim 13, wherein, during write operations of the cryogenic superconductive memory array, the voltage input is applied across the FE layer and an accessed cell of the cryogenic superconductive memory array receives a write voltage and unaccessed cells of the cryogenic superconductive memory array receive zero voltage.

15. The cryogenic superconductive memory array as set forth in claim 14, wherein, during the write operations of the cryogenic superconductive memory array, half-accessed cells of the cryogenic superconductive memory array receive a voltage that is less than the write voltage.

16. The cryogenic superconductive memory array as set forth in claim 13, wherein, during read operations of the cryogenic superconductive memory array, a heater cryotron device of an accessed cell of the cryogenic superconductive memory array is brought to a superconducting state and a read current flows through the heater cryotron device of the accessed cell.

17. The cryogenic superconductive memory array as set forth in claim 16, wherein, during the read operations of the cryogenic superconductive memory array, heater cryotron devices of unaccessed cells of the cryogenic superconductive memory array are brought to a resistive state.

18. A cryogenic superconductive electronic assembly, comprising:
a cryogenic superconductive logic gate assembly, comprising a first electrode substrate; a first ferroelectric (FE) layer carried by the first electrode substrate, the first FE layer exhibiting a first polarization state or a second polarization state based upon application of a voltage input across the first FE layer; at least one first superconducting quantum interference device (SQUID) residing on the first FE layer; and a first heater cryotron device situated adjacent the at least one first superconducting quantum interference device;
wherein a superconducting state of the at least one first superconducting quantum interference device is effected at the first polarization state of the first FE layer, constituting a logic state zero (0) of the cryogenic superconductive logic gate assembly, and a nonsuperconducting state of the at least one first superconducting quantum interference device is effected at the second polarization state of the first FE layer, constituting a logic state one (1) of the cryogenic superconductive logic gate assembly; and
a cryogenic superconductive memory array, comprising: a second electrode substrate; a second ferroelectric (FE) layer carried by the second electrode substrate; a plurality of second superconducting quantum interference devices (SQUIDs) residing on the second FE layer; and a plurality of second heater cryotron devices situated adjacent the second superconducting quantum interference devices, adjacent second heater cryotron devices and second superconducting quantum interference devices exhibit a series arrangement with respect to each other;
wherein, in order to execute read and write operations of the cryogenic superconductive memory array, a polarization state of the second FE layer is switchable between first and second polarization states via application of a voltage input across the second FE layer.

19. The cryogenic superconductive electronic assembly as set forth in claim 18, wherein the cryogenic superconductive logic gate assembly comprises a cascading configuration of cryogenic superconductive logic gate assemblies.

20. The cryogenic superconductive electronic assembly as set forth in claim 19, wherein, during write operations of the cryogenic superconductive memory array, the voltage input is applied across the second FE layer and an accessed cell of the cryogenic superconductive memory array receives a write voltage and unaccessed cells of the cryogenic superconductive memory array receive zero voltage, and wherein, during read operations of the cryogenic superconductive memory array, a second heater cryotron device of an accessed cell of the cryogenic superconductive memory array is brought to a superconducting state and a read current flows through the second heater cryotron device of the accessed cell.
